(19) United States
(12) Patent Application Publication
(10) Pub. No.: US 2009/0298296 A1
(43) Pub. Date: Dec. 3, 2009

(54) SURFACE PATTERNING AND VIA MANUFACTURING EMPLOYING CONTROLLED PRECIPITATIVE GROWTH

(75) Inventor: Dirk Burdinski, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/721,487

(22) PCT Filed: Dec. 12, 2005
(86) PCT No.: PCT/IB2005/054188

§ 371 Date: Jun. 12, 2007

(30) Foreign Application Priority Data
Dec. 20, 2004 (EP) 04106747.1

(51) Int. Cl. H01L 21/302

(52) U.S. Cl. 438/758; 257/E21.214

(57) ABSTRACT

The present invention is concerned with a process of surface patterning and via manufacturing employing controlled precipitative growth, and patterned substrates prepared by such a process according to the present invention. A process according to the present invention comprises providing a substrate including at least one surface on which it is required to pattern a material, the surface including at least first and second surface regions having distinct surface properties and wherein the first surface region is further provided with protective precipitative growth thereon, and applying at least one material to at least the second surface region, such that the applied material is either substantially not provided to the first surface region, or if provided to the first surface region can be selectively removed therefrom.

The present invention is concerned with a process of surface patterning and via manufacturing employing controlled precipitative growth, and patterned substrates prepared by such a process according to the present invention.

Patterning a material over a substrate is a common need and important process in modern technology, and is applied, for example, in microelectronics and display manufacturing. Patterning usually requires the deposition of a material over the entire surface of a substrate and its selective removal using photolithography and etching techniques. There is a need, however, for simpler and cheaper alternative patterning processes.

Soft lithographic patterning techniques have the potential for manufacturing processes, which are as simple and straightforward as those used in today's printing industry (B. Michel et al., Printing meets lithography: Soft approaches to high-resolution patterning. IBM Journal of Research & Development, 45(5), 697-719 (2001); Y. Xia and G. M. Whitesides, Soft Lithography. Angewandte Chemie, International Edition in English, 37, 550-575 (1998)). Microcontact printing (μCP) is a soft lithographic patterning technique that has the inherent potential for easy, fast and cheap reproduction of structured surfaces and electronic circuits with medium to high resolution (feature size currently ≧10 nm) even on curved substrates. It offers experimental simplicity and flexibility in forming various types of patterns by printing molecules from a stamp onto a substrate.

Patterning of metal layers by μCP is straightforward and has been demonstrated for a variety of metals, such as gold, silver, copper, palladium and platinum, and various metal oxides, such as aluminium oxide (with passivated oxide surfaces), silicon oxide, ITO and IZO. Conducting and semi-conducting layers of thin-film electronic devices can thus be patterned non-photolithographically using μCP. In order to manufacture entire devices non-photolithographically, however, a technique for also patterning insulating layers, such as polymer layers, is essential.

Patterning of polymeric layers by soft-lithography may be achieved by a variety of soft lithographic techniques. In an additive method, polymer layers can be grown from monomers on modified surfaces, such as those bearing patterned self-assembled monolayers (SAMs) adsorbed to a metal substrate or on surface treated polymer layers (R. M. Crooks, Patterning of Hyperbranched Polymer Films. Chem Phys Chem, 2, 645-654 (2001); N. L. Jeon et al., Patterned polymer growth on silicon surfaces using microcontact printing and surface-initiated polymerization. Applied Physics Letters, 75, 4201-4203 (1999)). This method is, however, limited to a very few dendritic polymers.

EP 1,192,505A describes a method of microtransfer patterning, in which a patterned stamp is brought into contact with a polymer layer on a first substrate and polymer material adheres to the protruding elements of the stamp. The stamp is then brought into contact with a second substrate, to which the polymer adheres stronger than to the stamp, and to which the patterned polymer layer is thus transferred upon removal of the stamp. The method suffers from the stringent requirements for a system with sufficient differences in adhesion properties of the different materials, such as the polymer, the stamp and the substrate material.

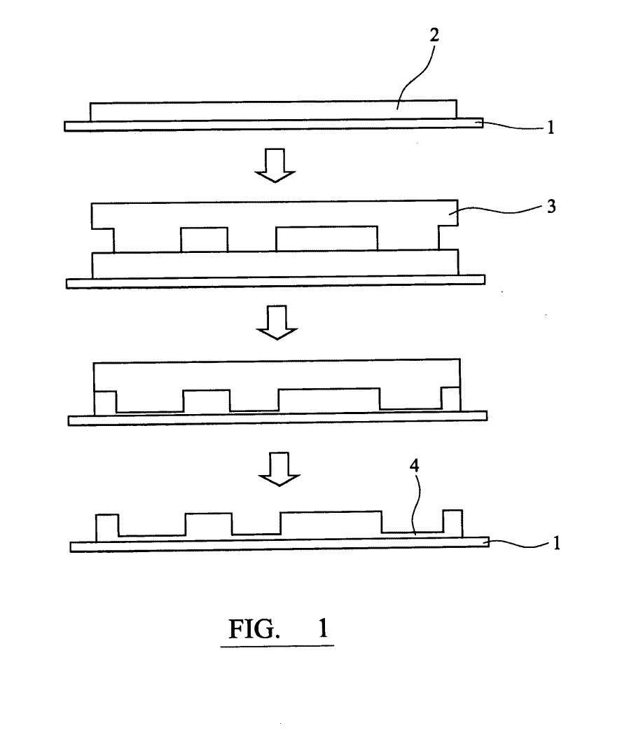

Alternative soft lithographic methods of polymer patterning are methods based on imprinting the pattern of a mold or stamp in moldable polymer compositions. Such methods are, for instance, soft embossing, solvent assisted micromolding (SAMIM), microtransfer molding (μTM), micromolding in capillaries (MIMIC) and replica molding (REM) (Y. Xia and G. M. Whitesides, Soft Lithography. Angewandte Chemie, International Edition in English, 37, 550-575 (1998); S. Holdcroft, Patterning B-Conjugated Polymers. Advanced Materials, 13, 1753-1765 (2001); Y. Xia, J. A. Rogers, K. E. Paul, and G. M. Whitesides, Unconventional Methods for Fabricating and Patterning Nanostructures. Chemical Reviews, 99, 1823-1848 (1999)). A common problem often associated with these techniques, however, is the low completeness of the polymer patterning, which can result in residual polymer layers in the recessed areas of the polymer pattern, as illustrated in FIG. 1. Furthermore, the polymer needs to be applied in, or transformed to, a moldable form, which significantly limits the range of usable polymers.

Electronic circuits (ICs) based partly or entirely on organic polymer material are foreseen to play a major role in the coming years in areas of electronics where low cost or flexibility is an essential requirement. Thus, the manufacturing of interconnects or vias in organic electrically insulating layers by non-photolithographic techniques is crucial for the completely non-photolithographic production of plastic electronic devices, for example as disclosed in U.S. Pat. No. 6,603,139.

U.S. Pat. No. 6,635,406 discloses a still photolithographic technique for via formation that uses the photosensitive material itself as the organic electrically insulating layer and thus does not require an additional photoresist layer. This method is limited, however, due to its dependence on photosensitive polymers and suffers from the generally very poor electronic properties of these materials.

A completely non-photolithographic method is disclosed in U.S. Pat. No. 6,400,024, which proposes via formation by rather crude mechanical micronotching.

A further problem that is encountered with prior art techniques is that metal layers comprising metal, such as gold or aluminium, are difficult to pattern by microcontact printing if their thickness exceeds some ten nanometers. The problem is the limited stability of the applied monolayer resist layer under the rather drastic etching conditions and the long etching time generally required to etch thicker metal layers. Therefore, additive rather than subtractive patterning methods are desired for the patterning of such thick metal layers.

To alleviate the problems associated with prior art techniques an additive patterning method is thus needed that allows the patterning of various layers as thick as a few hundred nanometers by microcontact printing. Ideally the method should be applicable to a large variety of different materials. A method that alleviates the problems of the prior art techniques is now provided by the present invention.

According to the present invention, therefore, there is provided a process of providing a substrate with a patterned material, which process comprises providing a substrate including at least one surface on which it is required to pattern a material, said surface including at least first and second surface regions having distinct surface properties and wherein said first surface region is further provided with protective precipitative growth thereon, and applying at least one material to at least said second surface region, such that said applied material is either substantially not provided to said first surface region, or if provided to said first surface region can be selectively removed therefrom.

In a particularly preferred embodiment, it is preferred that a process according to the present invention comprises positioning at least a first coating on the substrate surface such that the first surface region includes a first coating having a first surface property. It is further preferred that a process according to the present invention further comprises positioning at least a second coating on the substrate surface such that the second surface region includes a second coating having a second surface property, which is distinct from the first surface property of the first coating. Alternatively, the second surface region may include an underlying substrate surface that exhibits a second surface property, which is distinct from the first surface property of the first coating. A still further alternative is where the second surface region can include an underlying surface from which a previously applied coating, and where appropriate precipitative growth thereon, has or have been selectively removed, such that the exposed underlying substrate surface exhibits a second surface property, which is distinct from the first surface property of the first coating.

It is preferred that the first coating and when present the second coating positioned on said substrate respectively comprise first and second SAM-forming molecular species, the surface properties of which exhibit a significantly different precipitative growth rate with respect to precipitates grown in a process according to the present invention. If more than two different SAM-forming molecular species are applied, they may be selected such that they catalyse the growth of different kinds of crystal present in the grown precipitates, which may respectively have different chemical and physical properties. It is preferred that at least one, and more preferably each, of the SAM-forming molecular species is applied by microcontact printing. The size of the patterned areas defined by the applied SAMs determine the amount of precipitative growth on the substrate, which in turn determines the thickness of the applied material to be patterned in accordance with a process according to the present invention. It is preferred that essentially the total area of the precipitate enhancing SAM will be substantially covered with precipitative growth.

It is preferred that underlying substrate surface to which a SAM as described above is to be applied, and the SAM-forming species, should be selected together such that the SAM-forming species terminates at one end in a functional group that binds to the surface. It is also appreciated that in accordance with the principles of the present invention the SAM-forming species should be selected to exhibit surface properties which significantly differ with respect to promoting precipitative growth thereon.

An underlying substrate and SAM-forming molecular species are thus selected such that the molecular species terminates at a first end in a functional group that binds to the desired surface (the substrate or a surface film or coating applied thereto). As used herein, the terminology “end” of a molecular species, and “terminates” is meant to include both the physical terminus of a molecule as well as any portion of a molecule available for forming a bond with a surface in a way that the molecular species can form a SAM, or any portion of a molecule that remains exposed when the molecule is involved in SAM formation. A SAM-forming molecular species typically comprises a molecule having first and second terminal ends, separated by a spacer portion, the first terminal end comprising a functional group selected to bond to a surface (the substrate or a surface film or coating applied thereto), and the second terminal group optionally including a functional group selected to provide a SAM on the surface having a desirable exposed functionality. The spacer portion of the molecule may be selected to provide a particular thickness of the resultant SAM, as well as to facilitate SAM formation. Although SAMs of the present invention may vary in thickness, as described below, SAMs having a thickness of less than about 100 Angstroms are generally preferred, more preferably those having a thickness of less than about 50 Angstroms and more preferably those having a thickness of less than about 30 Angstroms. These dimensions are generally dictated by the selection of the SAM-forming molecular species and in particular the spacer portion thereof.

A wide variety of underlying surfaces (exposing substrate surfaces on which a SAM will form) and SAM-forming molecular species are suitable for use in the present invention. A non-limiting exemplary list of combinations of substrate surface material (which can be the substrate itself or a film or coating applied thereto) and functional groups included in the SAM-forming molecular species is given below. Preferred substrate surface materials can include metals such as gold, silver, copper, cadmium, zinc, nickel, cobalt, palladium, platinum, mercury, lead, iron, chromium, manganese, tungsten, and any alloys of the above typically for use with sulfur-containing functional groups such as thiols, sulfides, disulfides, and the like, in the SAM-forming molecular species; doped or undoped silicon with silanes and chlorosilanes; surface oxide forming metals or metal oxides such as silica, indium tin oxide (ITO), indium zinc oxide (IZO) magnesium oxide, alumina, quartz, glass, and the like, typically for use with carboxylic acids or heteroorganic acids including phosphonic, sulfonic or hydroxamic acids, alkoxylsilyl and halosilyl groups, in the SAM-forming molecular species; platinum and palladium typically for use with nitrites and isonitriles, in the SAM-forming molecular species. Additional suitable functional groups in the SAM-forming molecular species can include acid chlorides, anhydrides, hydroxyl groups and amino acid groups. Additional substrate surface materials can include germanium, gallium, arsenic, and gallium arsenide.

Preferably, however, an underlying exposing substrate surface on which a SAM will form for use in a process according to the present invention typically comprises a metal substrate, or at least a surface of the substrate, or a thin film or coating deposited on the substrate, on which the pattern is printed, comprises a metal, which can suitably be selected from the group consisting of gold, silver, copper, cadmium, zinc, nickel, cobalt, palladium, platinum, mercury, lead, iron, chromium, manganese, tungsten and any alloys of the above. Preferably the substrate, or at least a surface of the substrate on which the pattern is printed, comprises gold. The exposed substrate surfaces to be coated with a SAM may thus comprise a substrate itself, or may be a thin film or coating deposited upon a substrate, or may include patterned layers of conducting and insulating material. Where a separate substrate is employed, it may be formed of a conductive, nonconductive, semiconducting material, or the like.

In a preferred embodiment of the present invention, a combination of gold as an underlying substrate surface material on which is to be formed a SAM and a SAM-forming molecular species having at least one sulfur-containing functional group, such as a thiol, sulfide, or disulfide is selected. The interaction between gold and such sulfur-containing functional groups is well recognized in the art.

A SAM-forming molecular species may terminate in a second end opposite the end bearing the functional group selected to bind to particular substrate material in any of a variety of functionalities, provided that first and further surface properties are exhibited for first and further SAMs formed on a substrate surface in accordance with the present invention, which surface properties selectively promote or allow, or inhibit, precipitative growth thereon substantially as hereinbefore described. That is, the molecular species may include a functionality that, when the molecular species forms a SAM in the first surface region of the substrate, is exposed and can promote or allow selected precipitative growth thereon as required in accordance with the present invention. Alternatively, the molecular species may include a functionality that, when the molecular species forms a SAM in the second surface region of the substrate, is exposed and can inhibit said selected precipitative growth thereon as required in accordance with the present invention, although in certain embodiments of the present invention as hereinafter described in further detail the exposed functionality of the SAM in the second surface region of the substrate whilst inhibiting the selected precipitative growth occurring on the SAM in the first surface region can allow or promote different precipitative growth on the SAM in the second surface region. According to the same embodiments the functional group would literally define a terminus of the molecular species, while according to other embodiments the functional group would not literally define a terminus of the molecular species, but would be exposed.

The central portion of molecules comprising SAM-forming molecular species generally includes a spacer functionality connecting the functional group selected to bind to a surface and the exposed functionality. Alternatively, the spacer may essentially comprise the exposed functionality, if no particular functional group is selected other than the spacer. Any spacer that does not disrupt SAM packing is suitable. The spacer may be polar, nonpolar, positively charged, negatively charged, or uncharged. For example, a saturated or unsaturated, linear or branched hydrocarbon or halogenated hydrocarbon-containing group may be employed. The term hydrocarbon as used herein can denote straight-chained, branched and cyclic aliphatic and aromatic groups, and can typically include alkyl, alkenyl, alkynyl, cycloalkyl, cycloalkylalkyl, aryl, arylalkyl, arylalkenyl and arylalkynyl. The term “hydrocarbon containing group” also allows for the presence of atoms other than carbon and hydrogen, typically for example, oxygen and/or nitrogen. For example, one or more methylene oxide, or ethylene oxide, moieties may be present in the hydrocarbon-containing group; alkylated amino groups may also be useful. Suitably, the hydrocarbon groups can contain up to 35 carbon atoms, typically up to 30 carbon atoms, and more typically up to 20 carbon atoms. Corresponding halogenated hydrocarbons can also be employed, especially fluorinated hydrocarbons. In a preferred case the fluorinated hydrocarbon can be represented by the general formula F(CF₂)ₖ(CH₂)ₗ, where k is typically an integer having a value between 1 and 30 and l is an integer having a value of between 0 and 6. More preferably, k is an integer of between 5 and 20, and particularly between 8 and 18. It is of course recognized that although the above are given as preferred ranges for the values of k and l, the particular choice of k and l can be varied in accordance with the principles of the present invention. It will also be appreciated that the term “hydrocarbon containing group” also allows for the presence of atoms other than carbon and hydrogen, typically O or N, as explained above.

The above hydrocarbon spacer groups can also be further substituted by substituents well known in the art, such as C₁₋₆alkyl, phenyl, C₁₋₆haloalkyl, hydroxy, C₁₋₆alkoxy, C₁₋₆alkoxyalkyl, C₁₋₆alkoxyC₁₋₆alkoxy, aryloxy, keto, C₂₋₆alkoxycarbonyl, C₂₋₆alkoxycarbonylC₁₋₆alkyl, C₂₋₆alkylcarbonyloxy, arylcarbonyloxy, arylcarbonyl, amino, mono- or di-(C₁₋₆)alkylamino, or any other suitable substituents known in the art.

Thus, a SAM-forming molecular species generally comprises a species having the generalized structure R′-A-R″, where R′ is selected to bind to a particular surface of material, A is a spacer, and R″ is a group that is exposed when the species forms a SAM and is selected to exhibit a required surface property with respect to precipitative growth thereon in accordance with the present invention. Also, the molecular species may comprises a species having the generalized structure R″-A′-R′-A-R″, where A′ is a second spacer or the same as A, or R′″-A′-R′-A-R″, where R′″ is the same or different exposed functionality as R″.

Suitably, therefore, a SAM-forming molecular species can be selected from sulfur-containing molecules, such as alkyl- or aryl thiols, disulfides, dithiolanes or the like, carboxylic acids, sulfonic acids, phosphonic acids, hydroxamic acids or the like, or other reactive compounds, such as silyl halides or the like.

A particular class of molecules suitable for use as a SAM-forming molecular species for use with a gold, silver or copper substrate include functionalized thiols having the generalized structure R′-A-R″, where R′ can denote —SH, A can denote a hydrocarbon or halogenated hydrocarbon containing group, and R″ can denote a functional end group as described herein selected so as to respectively promote or allow, or inhibit, precipitative growth thereon in accordance with the present invention. The functional group, for example as represented by R″, which is arranged in use at the exposed end of the SAM-forming molecular species is of major importance for the physical and chemical properties of the deposited SAM. For example, ionic, nonionic, polar, nonpolar, halogenated, alkyl, aryl or other functionalities may exist at the exposed portion of the SAM and it is generally preferred in the context of the present invention that R″ is selected so as to impart hydrophobic or hydrophilic functionality to the SAM. If the exposed functionality of the SAM is a simple aromatic or aliphatic group, such as a hydrophobic alkyl or phenyl group, the SAM is hydrophobic. Alternatively, if the exposed functionality of the SAM is a polar, charged or protic functional group, then the SAMs will be substantially hydrophilic. Generally hydrophobic or positively charged hydrophilic SAMs tend to inhibit the precipitative growth, for example when R″ respectively denotes alkyl (such as C₁₋₆-alkyl, for example CH₃) or NX₃⁺, where X can represent hydrogen or C₁₋₆alkyl, for example CH₃, whereas hydrophilic neutral or negatively charged SAMs tend to promote or allow precipitative growth, for example when R″ denotes OH, CO₂⁻, SO₃⁻, PO₃⁻, and NO₂.

A locally significant difference of precipitative growth densities has been observed in accordance with the present invention for surfaces patterned with mixed hydrophilic and hydrophobic SAMs, exposing, for instance, hydrophilic carboxylic acid groups in some areas and hydrophobic alkyl groups in other areas. The difference has been seen to be even more pronounced when a surface is patterned with mixed SAMs exposing negatively charged carboxylate groups in some areas and with positively charged tetraalkylammonium groups in other areas.

SAMs provided according to the present invention can be formed by suitable techniques known in the art, for example by adsorption from solution, or from a gas phase, or may be applied by use of a stamping step employing a flat unstructured stamp or may be applied by a microcontact printing technique which is generally preferred for use in accordance with the present invention. Preferably, a patterned stamp defining a required pattern is loaded with an ink comprising the SAM-forming molecular species and is brought into contact with the surface of the substrate to be patterned, with the patterned stamp being arranged to deliver the ink to the contacted areas of the surface of said substrate.

Typically, a stamp employed in a method according to the present invention includes at least one indentation, or relief pattern, contiguous with a stamping surface defining a first stamping pattern. The stamp can be formed from a polymeric material. Polymeric materials suitable for use in fabrication of a stamp include linear or branched backbones, and may be cross linked or non-cross linked, depending on the particular polymer and the degree of formability desired of the stamp. A variety of elastomeric polymeric materials are suitable for such fabrication, especially polymers of the general class of silicone polymers, epoxy polymers and acrylate polymers. Examples of silicone elastomers suitable for use as a stamp include the chlorosilanes. A particularly preferred silicone elastomer is polydimethylsiloxane (PDMS).

Generally, a SAM-forming molecular species is dissolved in a solvent for transfer to a stamping surface. The concentration of the molecular species in such a solvent for transfer should be selected to be low enough that the species is well absorbed into the stamping surface, and high enough that a well-defined SAM may be transferred to a material surface without blurring. Typically, the species will be transferred to a stamping surface in a solvent at a concentration of less than 100 mM, preferably from about 0.5 to about 20.0 mM, and more preferably from about 1.0 to about 10.0 mM. Any solvent within which the molecular species dissolves, and which may be carried (e.g. absorbed) by the stamping surface, is suitable. In such selection, if a stamping surface is relatively polar, a relatively polar and/or protic solvent may be advantageously chosen. If a stamping surface is relatively nonpolar, a relatively nonpolar solvent may be advantageously chosen. For example, toluene, ethanol, THF, acetone, isooctane, cyclohexane, diethyl ether, and the like may be employed. When a siloxane polymer, such as polydimethyl siloxane elastomer (PDMS) as referred to above, is selected for fabrication of a stamp, and in particular a stamping surface, toluene, ethanol, cyclohexane, decalin, and THF are preferred solvents. The use of such an organic solvent generally aids in the absorption of SAM-forming molecular species by a stamping surface. When the molecular species is transferred to the stamping surface, either near or in a solvent, the stamping surface should be dried before the stamping process is carried out. If a stamping surface is not dry when the SAM is stamped onto the material surface, blurring of the SAM can result. The stamping surface may be air-dried, blow dried, or dried in any other convenient manner. The drying manner should simply be selected so as not to degrade the SAM-forming molecular species.

The term “protective precipitative growth” as used herein denotes precipitate formation, which can include precipitation of monocrystalline material, polycrystalline material, microcrystalline material and even amorphous material. The size of the crystals thus grown in accordance with a process according to the present invention may be varied between sub-micrometers and a few hundred micrometers. The crystal modification and the shape of the grown crystals can be controlled by the choice of the tail groups of the deposited monolayer molecules. The size of the crystals can further be controlled by the general crystal growth conditions, such as the types of chemicals present in a crystallisation solution, the method of generating a supersaturated solution to be crystallised, the crystallisation temperature and process conditions. Depending on the conditions, crystals can be grown within a few minutes or even faster.

Precipitative growth, and where appropriate crystals grown in accordance with the present invention, can be completely inorganic or at least partially organic materials, provided that they exhibit a sufficiently high solubility in water or polar solvents, including alcohols. Examples for partially organic material are metal formiates, metal triflates and the like. Preferably, precipitative growth in accordance with the present invention can include inorganic salt precipitates, such as calcite (CaCO₃), strontium carbonate, alum (KAl(SO₄)₂) and the like, and growth thereof can preferably be promoted on a hydrophilic SAM patterned on a substrate surface in accordance with the present invention. In certain embodiments, it is preferred that the precipitative growth is crystalline.

The properties of the applied coatings, preferably SAMs, can be selected so that the growth of more than one type of crystal is possible, and such coatings, preferably SAMs, can be generated by sequential coating steps, such as sequential μCP steps. In this way, a process according to the present invention may comprise effecting more than one type of selective crystal growth on the substrate surface, for example treating the substrate surface with more than one supersaturated salt solution, where the crystals to be respectively grown therefrom on the first and second surface regions, and preferably the respective coatings thereof, may be different or may include crystal modifications or polymorphic forms of the same chemical compound, and where the respective crystals to be grown will be dependent on the respective interactions thereof with the first and second surface regions, preferably the SAMs provided in first and second surface regions, in accordance with a process according to the present invention. The individual crystal modifications can be controlled locally by the type of exposed SAM functional group. As is recognized in the art, different crystal modifications have different physical properties and the crystals grown on the different surface coatings or SAMs may, for instance, show different kinetics during dissolution in a given solvent, so that only one crystal modification may be removed completely by dissolution, while the other crystal modification dissolves significantly slower and remains on the surface.

Alternatively, crystals of different chemical compounds may be grown on the first and second surface regions of the substrate, such as the first and second SAMs provided in the first and second surface regions of the substrate, in parallel or sequentially. The selectivity in crystal growth can once again originate from the differences in the surface properties of the different SAMs. The chemically different composition of the crystals in this case can facilitate selective removal of one type of crystal while the other crystal form remains substantially unchanged. The combination of selecting different crystals and depositing different material sequentially provides an enormous potential and flexibility for the patterning of multilayer stacks of different materials.

Precipitative growth may be performed from solution or the gas phase. Preferentially, crystals will be grown from a supersaturated solution of the respective compound. The supersaturated solution may contain various additives that support and allow control of the precipitative growth process. It is preferred the substrate surface is treated with one or more supersaturated solutions of one or more compounds to be precipitated, wherein the surface characteristics of the first and second surface regions (preferably the first surface property of the first coating, the second surface property of the second coating and where appropriate any further coatings, or a further portion of the surface) and the supersaturated solution or solutions, are respectively such that precipitative growth selectively forms on the first surface region of the substrate surface substantially as hereinbefore described. In certain embodiments as explained above, it may also be preferred to provide crystals of different chemical compounds or different crystal structure on the first and second surface regions of the substrate, such as first and second SAMs provided in the first and second surface regions of the substrate, in parallel or sequentially. The chemically different composition of the crystals in this case can facilitate selective removal of one type of crystal while the other crystal form remains substantially unchanged.

Suitable solvents for the supersaturated solution can include organic and inorganic solvents. The solvent, if used, should be compatible with the compound of interest to be grown on an underlying substrate surface. That is, the compound of interest must be soluble in the solvent, and the solution must be capable of supersaturation and the solvent should be selected accordingly. Those of skill in the art will be able to match an appropriate solvent to the chosen compound of interest. Once a compound of interest is selected for producing precipitative growth, the appropriate solvent can be selected. Those of ordinary skill in the art can determine the appropriate solvent for a selected compound of interest without undue experimentation.

It may be preferred that the material to be patterned is applied selectively to the second surface region of the substrate, which is substantially free from precipitative growth. The second surface region can include a coating, such as a SAM, or can comprise an underlying substrate surface from which a previously applied coating, and where appropriate associated precipitative growth, has or have been selectively removed. In certain embodiments, however, the patterned material can be applied to both (i) the second surface region and (ii) protective precipitative growth provided in the first surface region, wherein application in (ii) is such as to allow subsequent selective removal of the precipitative growth and patterned material applied thereto. Application of the patterned material to the precipitative growth may effect partial or non-homogeneous covering of the precipitates, for example it may be that the thickness of the applied patterned material will not be homogeneous, with the applied patterned material being of reduced thickness in the upper vertical regions of the protective precipitative growth, so as to facilitate precipitate removal as hereinafter described in greater detail. Application of the material to be patterned can be by any suitable method, including vacuum deposition techniques or solution processing. Deposition may be by gas phase deposition, sputtering, electroless deposition, electrodeposition, spin coating, drop casting or the like.

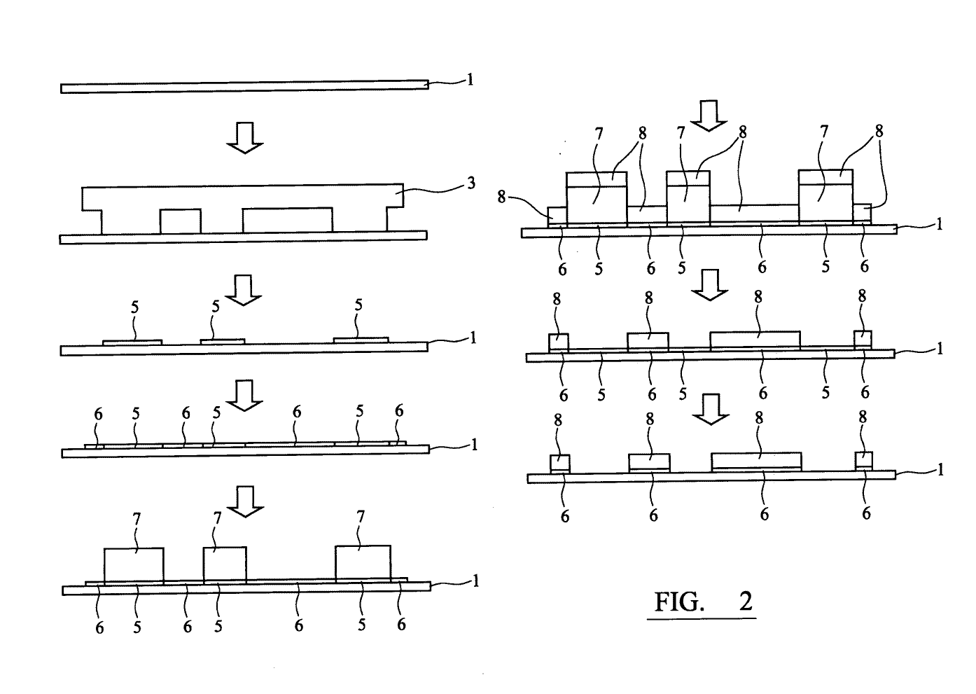

A process involving anisotropic gas phase deposition of the material to be patterned is illustrated in FIG. 2. As a result of the anisotropy of the deposition step, material deposition on top of the precipitative growth is not a problem as this is removed in the subsequent precipitate dissolution step automatically, since it is completely separated from the rest of the deposited material. Precipitative growth is suitably removed by dissolution in a preferably aqueous solution containing additives, if necessary. Depending on the type of precipitate or crystals, other solvents, such as alcohols may be used. Since most crystals are soluble in water or very hydrophilic alcohols, removal thereof does not affect the remaining deposited materials separate from the deposited crystals, which either would require an aggressive etching solution to be attacked (metals) or a significantly less polar organic solvent, for example in the case of oligomers, polymers, aromatic compounds and the like.

After removal of the precipitative growth from the substrate, an underlying coating, typically a SAM, can if desired be subsequently removed, such as for example removal of the hydrophilic SAM as illustrated in FIG. 2, for instance by an oxygen or argon plasma treatment.

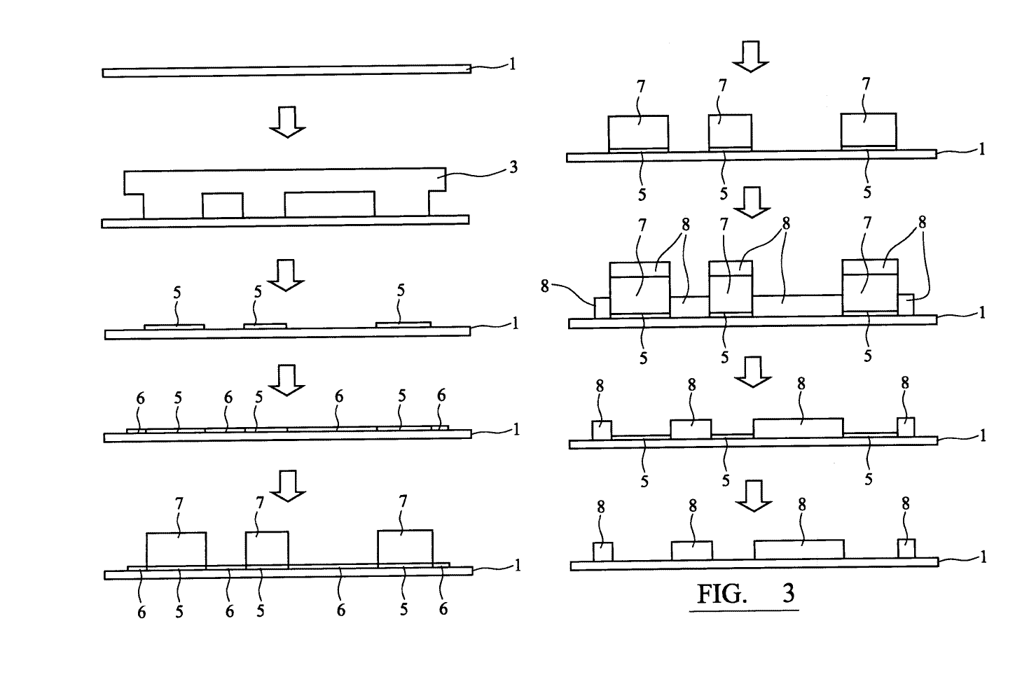

In certain embodiments of the present invention it may be required that prior to application of the material to be patterned, it may be desired to remove a coating, preferably the SAM, which inhibited precipitative growth thereon. For example, if desired a hydrophobic SAM may be removed prior to the deposition of the patterned material, as illustrated in FIG. 3. This again can be done by a variety of methods, and preferably a plasma treatment can be used.

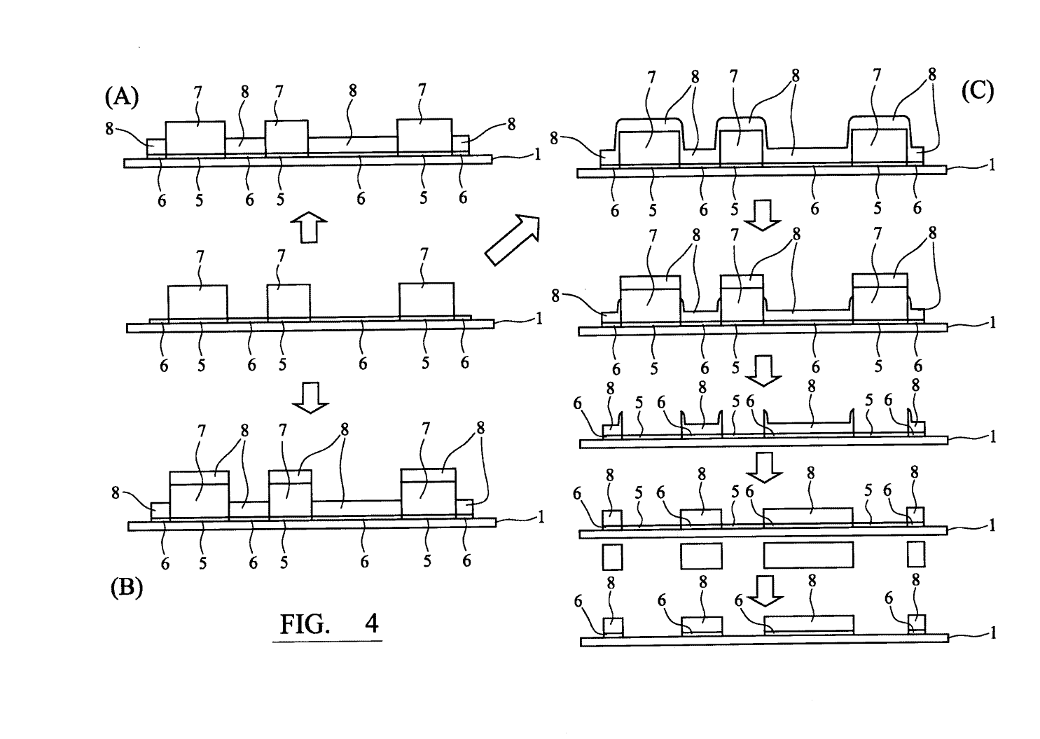

In the application of the material to be patterned in a process according to the present invention it may be preferable that the material to be patterned only partially covers the underlying precipitative growth in order to allow easy dissolution of the precipitative growth thereafter. One possibility to achieve this is anisotropic deposition of the patterned material and where the material (or a solution of the material that is used for deposition) is sufficiently hydrophobic and the precipitative growth surface is sufficiently hydrophilic (or vice versa), the patterned material will have a low tendency to spread on the surface of the precipitative growth. This will result in spontaneous dewetting of crystals present in the precipitative growth and thus a selective deposition of the patterned material only in the remaining areas, as shown in FIG. 4.

If, however, a complete coverage of the precipitative growth cannot be avoided by the material to be patterned, in certain embodiments of a process in accordance with the present invention, therefore, additional process steps may be necessary. For example, the layer thickness of the applied patterned material will not be homogeneous, in particular as illustrated in FIG. 4 the applied patterned material will be of reduced thickness in the upper vertical regions of the coated surface of the substrate, and as such the overall thickness can be reduced in an isotropic etching process so as to uncover underlying precipitative growth as shown in FIG. 4. This will allow selective dissolution of the underlying precipitative growth and removal of the material remaining thereon. A subsequent polishing step may be desired to remove remaining protruding material residues.

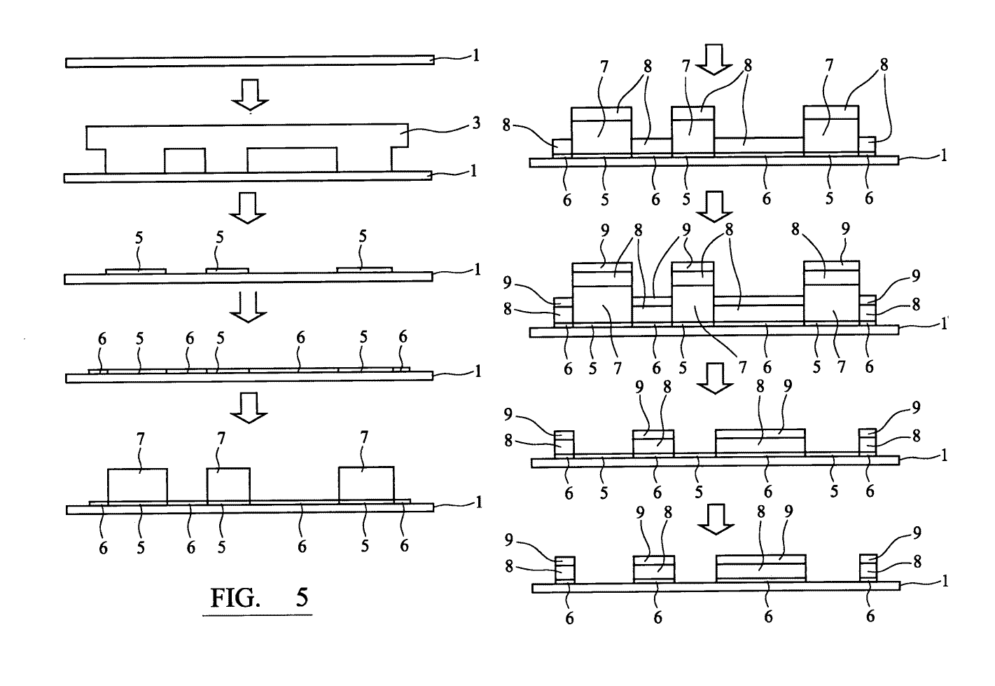

A process according to the present invention is not restricted to the application of a single patterning layer and for example depending on the size of crystals present in the precipitative growth and the thickness of the desired layers, several patterning layers may be deposited as shown in FIG. 5. Since crystals may be grown as large as a few hundred micrometers, a manifold of layers or very thick patterning layers can easily be deposited and patterned in a single process according to the present invention.

A process according to the present invention is highly suited to pattern and form vias in electrically insulating polymeric layers, such as those required in plastic electronic devices. Furthermore, a process according to the present invention can be used to pattern very thick layers of difficult to etch metals such as gold or platinum. Furthermore, a process according to the present invention is suitable for patterning a wide variety of materials, including metals that have hitherto not been accessible to patterning via microcontact printing as well as most polymeric materials.

There is further provided by the present invention a patterned substrate obtained by a process substantially as hereinbefore described. Suitably a patterned substrate according to the present invention is suitable for use in microelectronics or display manufacturing and it will be appreciated that in certain embodiments of the present invention the patterned substrate prepared thereby can provide interconnects or vias in electrically insulating materials produced according to microcontact printing techniques of the present invention.

There is also provided by the present invention a process of manufacturing an electronic device which includes a substrate provided with patterned material substantially as hereinbefore described, which patterned substrate is prepared by a process according to the present invention. Electronic devices suitably prepared by the present invention include driver electronics of display devices, and organic electronic devices in general. More specifically, a process according to the present invention can provide electronic devices that include organic electronic circuits, and such devices can be selected from the group consisting of LCD, small molecule LEDs, polymer LEDs, electrophoretic (E-ink type) displays, plastic RF (radio frequency) tags and biosensors. In particular an electronic device as provided by the present invention can comprise an organic electronic circuit including driver electronics of LCD or LED displays.

The present invention will now be further illustrated by the following Figures and Experimental, which do not limit the scope of the invention in any way.

FIG. 1 is a schematic representation of prior art embossing/molding techniques.

FIG. 2 is a schematic representation of a single layer patterning process according to the present invention, which includes anisotropic deposition of the patterned material on the substrate.

FIG. 3 is a schematic representation of a single layer patterning process according to the present invention, which includes anisotropic deposition of the patterned material on the substrate and wherein the SAM without precipitative growth is removed prior to the anisotropic deposition.

FIG. 4 is a schematic representation of single layer patterning process according to the present invention, and further illustrates (i) anisotropic deposition, (ii) selective deposition, and (iii) isotropic deposition.

FIG. 5 is a schematic representation of a multi layer patterning process according to the present invention.

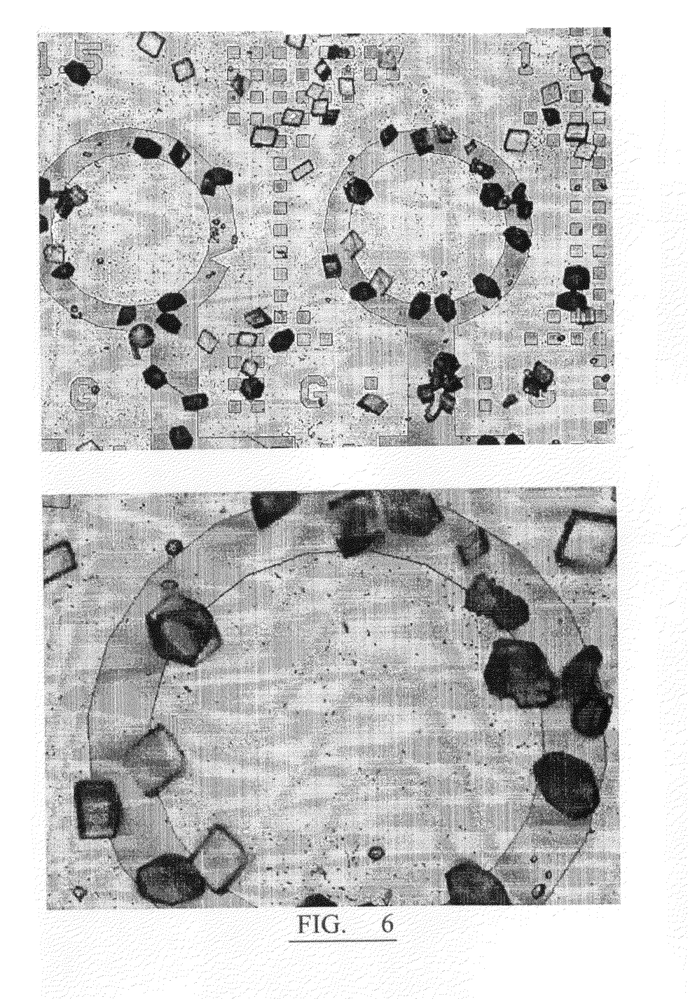

FIG. 6 shows optical micrographs of a top gold sample, which was pre-patterned with two different SAMs and then subjected to the selective precipitation of calcium carbonate crystals as described in Example 1.

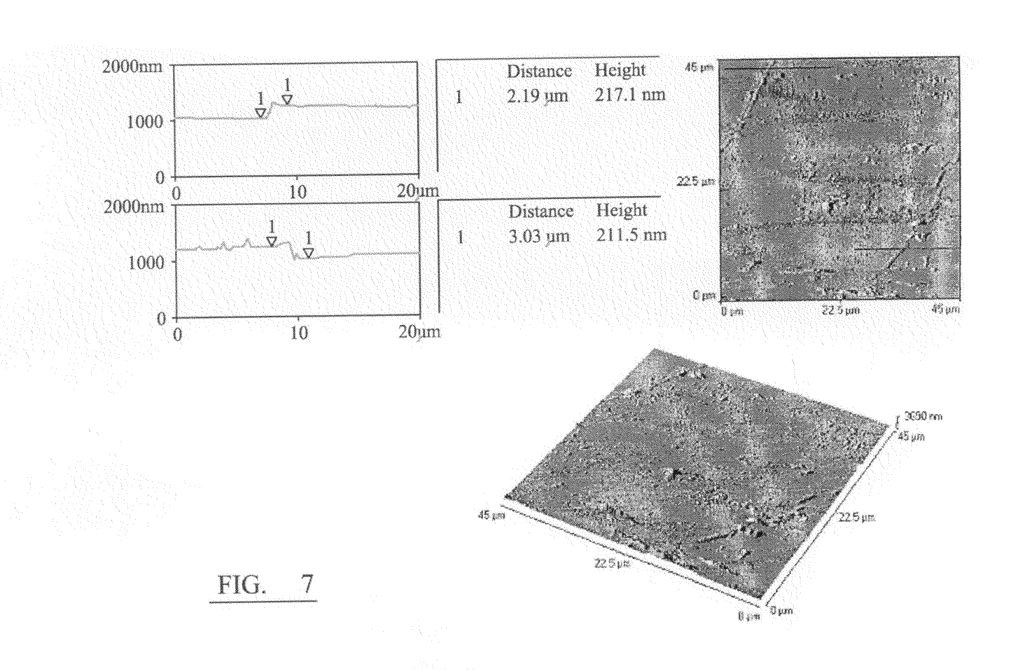

FIG. 7 is the result of an AFM scan of the larger ring structures as shown in FIG. 6.

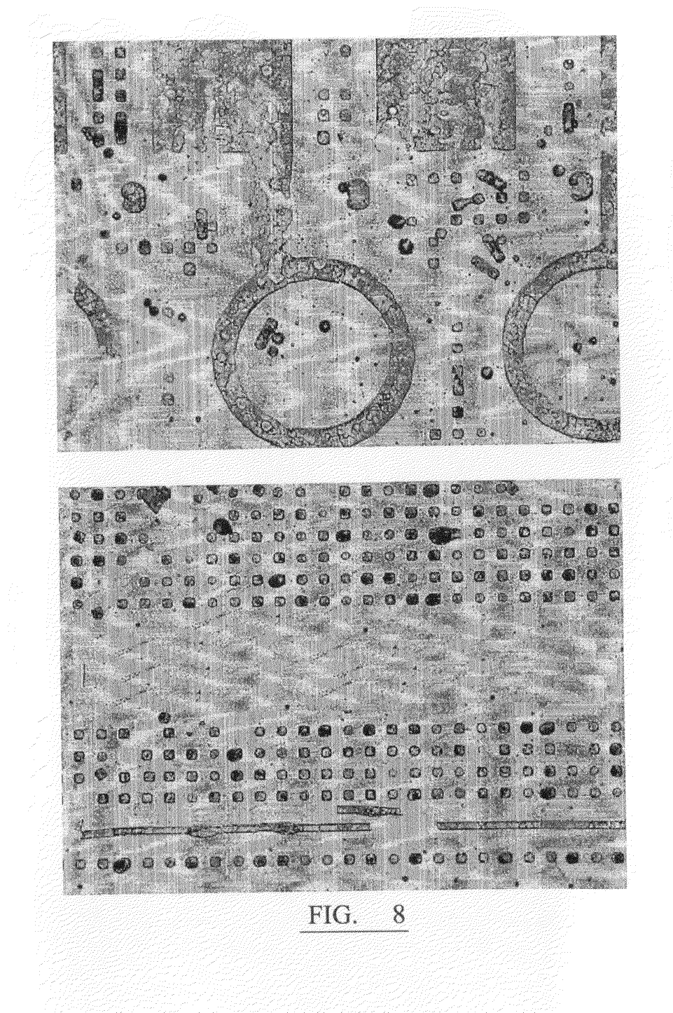

FIG. 8 shows optical micrographs of a top gold sample, which was pre-patterned with two different SAMs and then subjected to the selective precipitation of potassium aluminum sulfate as described in Example 2.

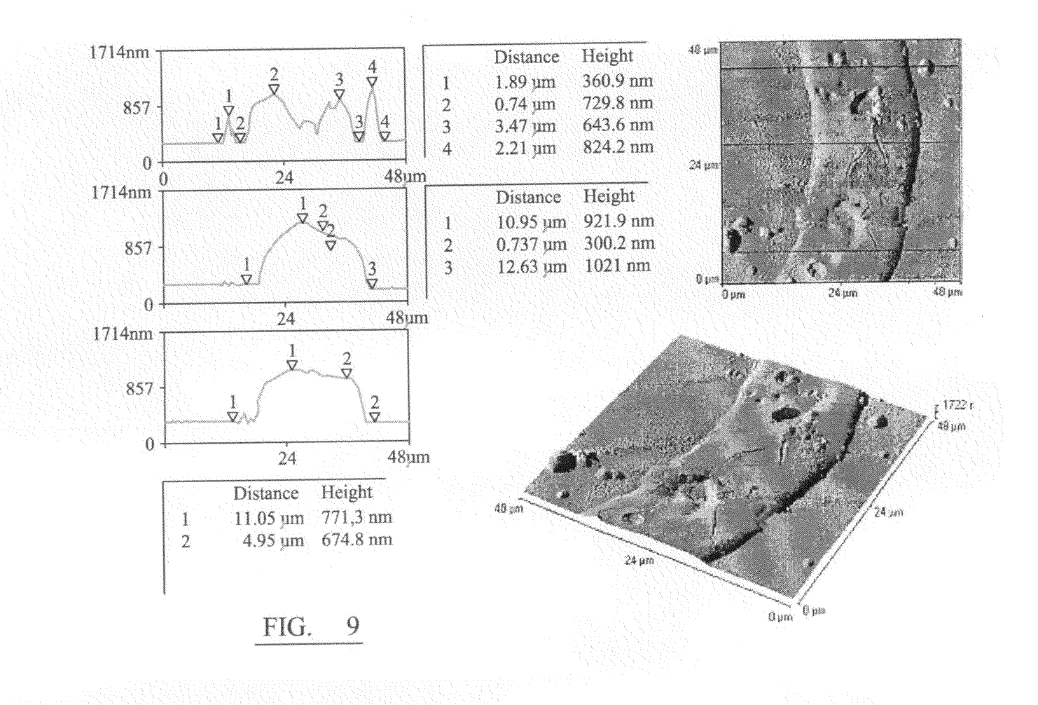

FIG. 9 is the result of an AFM scan of the larger ring structures as shown in FIG. 8.

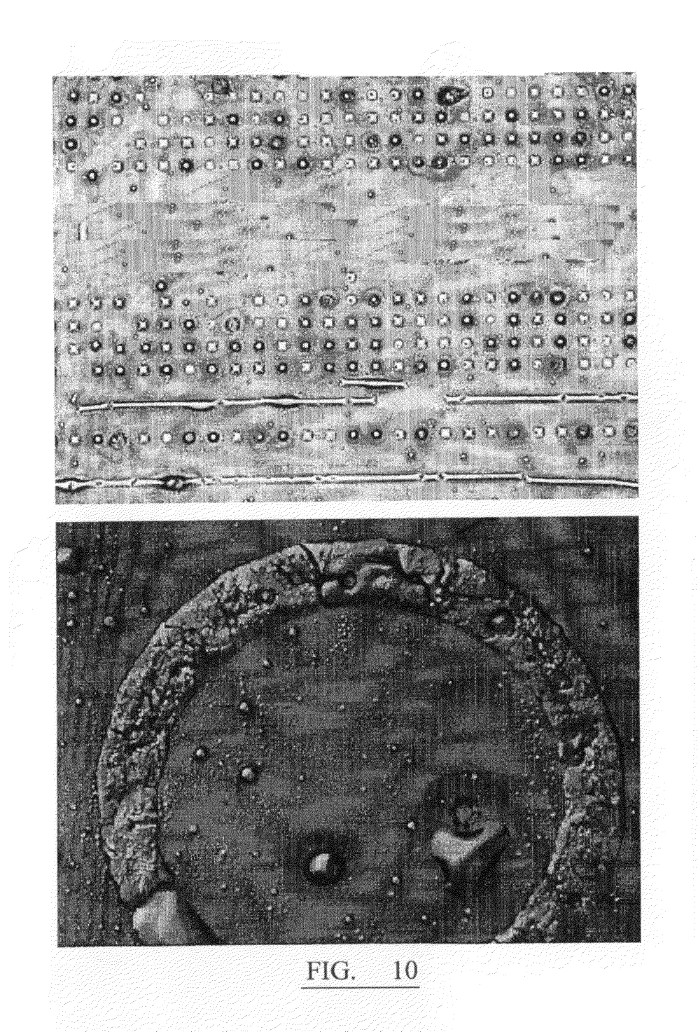

FIG. 10 shows optical micrographs of a top gold sample, which was pre-patterned with two different SAMs and then subjected to the selective precipitation of potassium aluminum sulfate followed by spin-coating with a chloroform solution of poly(3-n-hexylthiophene) as described in Example 2.

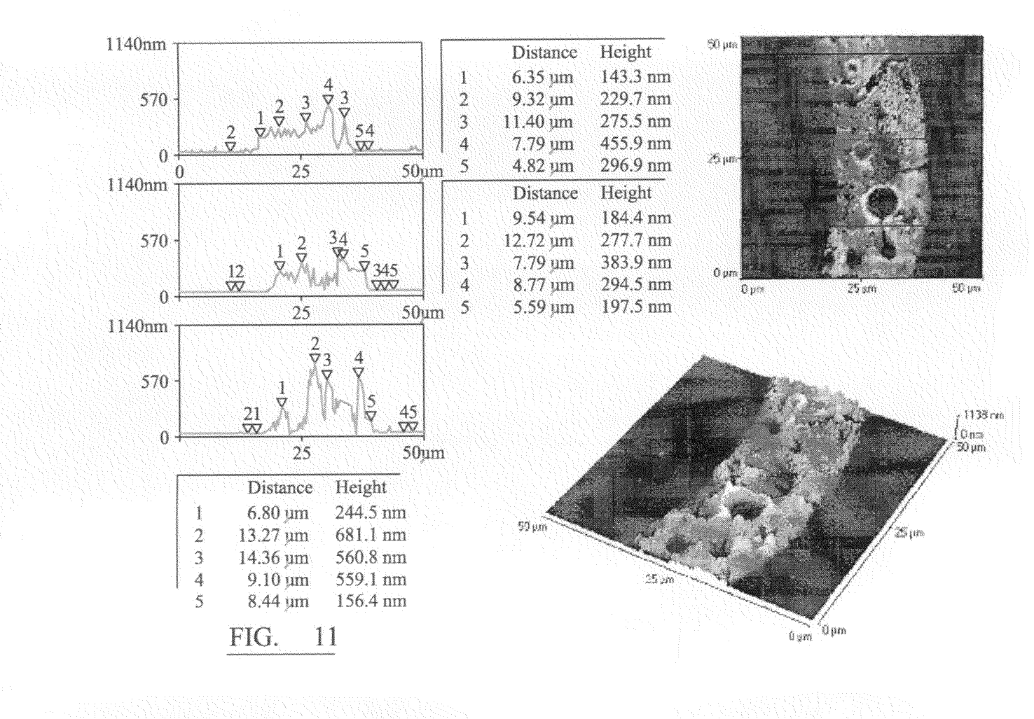

FIG. 11 is the result of an AFM scan of the larger ring structures as shown in FIG. 10.

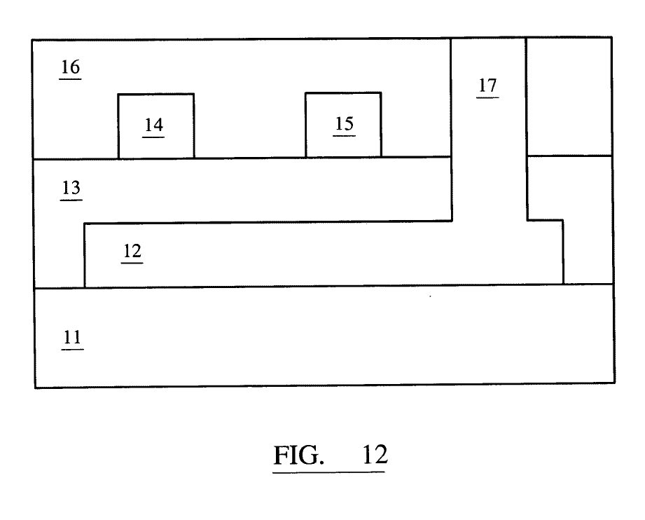

FIG. 12 is a cross section of a layer structure of a basic bottom-gate organic FET suitable for use in an organic electronic circuit, and which includes a patterned substrate as provided by the present invention.

With specific reference to FIG. 1, there is shown a process according to the prior art wherein a substrate (1) is provided with a polymer coating (2). A stamp or mold (3) is then brought into contact with polymer coating (2) so as to form a desired pattern of the polymer on substrate (1). Such patterning according to prior art techniques can, however, result in residual polymer layers (4) remaining in the recessed areas of the polymer pattern on substrate (1).

With specific reference to FIG. 2, there is shown a substrate (1) and a stamp (3) used to apply a hydrophilic SAM (5) to substrate (1). Hydrophobic SAM (6) is subsequently applied to substrate (1). Crystals (7) are subsequently selectively grown on hydrophilic SAM (5). Patterned material (8) is subsequently applied by anistropic deposition to both hydrophobic SAM (6) and crystals (7). Crystal dissolution is then carried out to selectively remove crystals (7) and patterned material (8) thereon so as to leave substrate (1) patterned with patterned material (8) overlying hydrophobic SAM (6) and hydrophilic SAM (5). Hydrophilic SAM (5) is then selectively removed so as to leave substrate (1) patterned with patterned material (8) overlying hydrophobic SAM (6).

With specific reference to FIG. 3, there is shown a substrate (1) and a stamp (3) used to apply a hydrophilic SAM (5) to substrate (1). Hydrophobic SAM (6) is subsequently applied to substrate (1). Crystals (7) are subsequently selectively grown on hydrophilic SAM (5). Hydrophobic SAM (6) is then selectively removed. Patterned material (8) is subsequently applied by anistropic deposition to the exposed surface of substrate (1) and crystals (7). Crystal dissolution is then carried out to selectively remove crystals (7) and patterned material (8) thereon so as to leave substrate (1) patterned with patterned material (8) and hydrophilic SAM (5). Hydrophilic SAM (5) is then selectively removed so as to leave substrate (1) patterned with patterned material (8) directly applied to the surface of substrate (1).

With specific reference to FIG. 4, there is shown a substrate (1) provided with hydrophilic SAM (5), hydrophobic SAM (6) and crystals (7) are subsequently selectively grown on hydrophilic SAM (5). Patterned material (8) can be subsequently applied by selective deposition method (A), anisotropic deposition method (B) or isotopic deposition method (C). In selective deposition method (A), patterned material (8) is selectively applied to underlying hydrophobic SAM (6). In anisotropic deposition method (B), patterned material (8) is applied to both hydrophobic SAM (6) and to crystals (7). In isotropic deposition method (C), patterned material (8) is applied to both hydrophobic SAM (6) and to crystals (7) and the non-homogeneous nature of the deposition can clearly be seen with patterned material (8) being of reduced thickness in the upper vertical regions of the crystals (7). The overall thickness of patterned material (8) is reduced further in the upper vertical regions of the crystals (7) by an isotropic etching process which is followed by crystal dissolution to selectively remove crystals (7) and the majority of adjacent patterned material (8). Polishing is then carried out so as to leave substrate (I) patterned with patterned material (8) overlying hydrophobic SAM (6) and hydrophilic SAM (5). Hydrophilic SAM (5) is then selectively removed so as to leave substrate (1) patterned with patterned material (8) overlying hydrophobic SAM (6).

With specific reference to FIG. 5, there is shown a substrate (1) and a stamp (3) used to apply a hydrophilic SAM (5) to substrate (1). Hydrophobic SAM (6) is subsequently applied to substrate (1). Crystals (7) are subsequently selectively grown on hydrophilic SAM (5). Patterned material (8) is subsequently applied by anistropic deposition to both hydrophobic SAM (6) and crystals (7). Patterned material (9) is subsequently applied by anistropic deposition to patterned material (8). Crystal dissolution is then carried out to selectively remove crystals (7) and patterned materials (8) and (9) thereon so as to leave substrate (1) patterned with patterned materials (8) and (9) overlying hydrophobic SAM (6) and hydrophilic SAM (5). Hydrophilic SAM (5) is then selectively removed so as to leave substrate (1) patterned with patterned materials (8) and (9) overlying hydrophobic SAM (6).

With specific reference to FIG. 12, (11) is a substrate carrier (for example, a polymer, glass, or silicon) and (12) is a gate electrode (for example, gold, patterned by for example μCP). (13) is a spin-coated insulating layer, which is patterned in accordance with the present invention (printing at least one SAM on the gold layer (12), formation of precipitative growth on the printed SAM, spincoating insulating layer (13), and removing precipitative growth). (14) and (15) are the source and drain electrode in the source-drain layer (for example, also gold, patterned by for example μCP). (16) is a layer of an organic semiconductor (spincoated or evaporated and patterned in accordance with the present invention). (17) is a via through the insulating layer (13) and the semiconducting layer (16), which allows for making external electrical contact with the bottom gate layer (12). (17), spanning both layers (13) and (16), is formed using precipitative growth, which is removed in a final process step and replaced by a gold contact, for example by electrodeposition or electroless deposition of the gold.

### EXPERIMENTAL

### Example 1

A soft lithographic stamp was replicated from a master using a regular PDMS precursor (SYLGARD 184, Dow Corning) and a common curing procedure.

On a regular silicon wafer was grown a thermal oxide layer of about 500 nm thickness. Subsequently a titanium adhesion layer (about 5 nm) was sputtered thereon, followed by a top gold layer with a thickness of about 20 nm. The surface was rinsed successively with water, ethanol, and n-heptane. In a final cleaning step the substrate was exposed to an argon plasma (0.25 mbar, 300 W, 5 minutes) immediately prior to printing.

An ink solution was prepared by dissolving mercaptohexadecanoic acid (for SAM 1, 10 mM) in ethanol. A PDMS stamp was immersed in this solution and inked for about 2 hours. After removal from the ink solution, it was rinsed with ethanol and dried in a stream of nitrogen. It was then brought into contact with the gold surface of the substrate for about 20 seconds and removed again.

The substrate was subsequently immersed in a solution of N,N,N-trimethyl(11-mercaptoundecyl)ammonium chloride (for SAM 2, 10 mM) in ethanol for about one hour to deposit SAM 2 in the remaining areas of the gold surface that were not covered with the printed SAM 1. It was then rinsed with ethanol and dried in a stream of nitrogen.

In the next step the surface-modified substrate was immersed in an aqueous solution of calcium chloride (10 mM) in such a way that the substrate was held about 1 cm above the bottom of the container and the modified surface pointed downwards being parallel oriented to the bottom. This assembly was then placed in a closed dessicator loaded with an excess amount of solid ammonium carbonate ((NH₄)₂CO₃), to initiate gas phase diffusion of ammonium carbonate into the calcium chloride solution and the growth of calcium carbonate crystals on the modified gold surface of the substrate.

The substrate was removed after about 1 hour from the solution and rinsed with clean water, ethanol, and n-heptane before drying in a stream of nitrogen.

FIG. 6 shows an optical micrograph of a so treated substrate. The darker areas are those resembling the pattern of the stamp. They were initially modified with SAM 1. The lighter areas are those modified with SAM 2. The darker colour of the regular square features with a nominal width of 10 micrometers indicates the selective deposition of crystalline CaCO₃ salt on top of the SAM 1. There is also visible some further homogeneously distributed monocrystalline CaCO₃ precipitate, which can be removed easily mechanically, due to the very large size of these crystals.

FIG. 7 shows the result of an AFM scan of the larger ring structures previously shown in FIG. 6. The height profile measured at the edge of these ring structures shows an average height difference between the elevated salt-covered areas and the not salt-covered areas of about 215 nm.

### Example 2

A sample was prepared as described in Example 1 including surface patterning with a printed SAM 1 and an adsorbed SAM 2 in the unmodified areas on the top gold layer.

The substrate was immersed in a small volume of a saturated solution of potassium aluminium sulfate (KAl(SO₄)₂, alum) in water in such a way that the gold surface pointed upwards. The solution was then quickly diluted with a large volume of ethanol in order to reduce the solubility of the alum and hence cause precipitation of alum crystals on the substrate surface. Thereafter the substrate was immediately removed from the solution and rinsed with ethanol before drying in a stream of nitrogen.

FIG. 8 shows optical micrographs of a so treated substrate. The regular squares visible in the pattern have a nominal width of 10 micrometers. The crystalline alum precipitate clearly resembles the pattern of the printed SAM 1 comprising square features, letters, and larger ring structures. No crystal precipitation in visible in the remaining areas, which are covered with SAM 2.

FIG. 9 shows the result of an AFM scan of the larger ring structures already shown in FIG. 8. The height profile measured at the edge of these ring structures shows a height difference between the elevated salt-covered areas and the not salt-covered areas of about 500-1000 nm. Such a height difference is sufficient for patterning layers of a few hundred nanometers.

FIG. 10 shows optical micrographs of a so prepared substrate further treated by spin-coating with a chloroform solution of poly(3-n-hexylthiophene) (M_{w}=40,000 g mol⁻¹), indicating a conserved height difference caused by the crystal precipitation even after the spin-coating process.

FIG. 11 shows the result of a respective AFM scan of the larger ring structures as previously shown in FIG. 10. According to these measurements, the height difference between elevated (salt-covered) areas and the remaining areas was reduces from initially about 500-1000 nm before spin-coating to about 200-400 nm after spin-coating indicating a preferred deposition of the polymeric material in the depressed regions of the pattern.

It should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. The invention may be implemented by means of hardware comprising several distinct elements, and by means of a suitably programmed computer. In a device claim enumerating several means, several of these means may be embodied by one and the same item of hardware. The mere fact that certain measures are recited in mutually different dependent claims does not indicate that a combination of these measures cannot be used to advantage.

1. A process of providing a substrate with a patterned material, which process comprises providing a substrate including at least one surface on which it is required to pattern a material, said surface including at least first and second surface regions having distinct surface properties and wherein said first surface region is further provided with protective precipitative growth thereon, and applying at least one material to at least said second surface region, such that said applied material is either substantially not provided to said first surface region, or if provided to said first surface region can be selectively removed therefrom.

2. A process according to claim 1, wherein either said first surface region or second surface region includes a SAM-forming molecular species.

3. A process according to claim 2, wherein said first surface region includes a first SAM-forming molecular species and said second surface region includes a second SAM-forming molecular species.

4. A process according to claim 2, wherein at least one SAM-forming molecular species is applied by microcontact printing.

5. A process according to claim 2, wherein the exposed functionality of said SAM-forming molecular species can selectively allow, promote or inhibit precipitative growth thereon.

6. A process according to claim 1, wherein said precipitative growth comprises a salt precipitate.

7. A process according to claim 1, wherein said material is selectively applied to said second surface region of said substrate surface.

8. A process according to claim 1, wherein said material is applied to (i) said second surface region, and (ii) said protective precipitative growth provided to said first surface region, wherein application in (ii) is such as to allow subsequent selective removal of said precipitative growth and material applied thereto.

9. A process of manufacturing an electronic device which includes a substrate provided with a patterned material as defined in claim 1, which patterned substrate is prepared by a process as defined in claim 1.

10. A process according to claim 9, wherein said electronic device is an organic electronic circuit including driver electronics of LCD or LED displays.
